(19) United States
(12) Patent Application Publication
(10) Pub. No.: US 2026/0231605 A1
(43) Pub. Date: Aug. 6, 2026

(54) LIGHT-EMITTING ELEMENT, ELECTRONIC DEVICE INCLUDING THE SAME, AND METHOD FOR MANUFACTURING THE LIGHT-EMITTING ELEMENT

(71) Applicant: Samsung Display Co., LTD., Yongin-si (KR)

(72) Inventor: JUNGSUB HWANG, Yongin-si (KR)

(21) Appl. No.: 19/382,723

(22) Filed: Nov. 7, 2025

(30) Foreign Application Priority Data
Feb. 4, 2025 (KR) 10-2025-0014014

(51) Int. Cl. H10K 50/16; H10K 50/115; H10K 50/15; H10K 71/13; H10K 102/00

(52) U.S. Cl. CPC H10K 50/166; H10K 50/115; H10K 71/135; H10K 50/15; H10K 2102/351

(57) ABSTRACT

In a method for manufacturing a light-emitting element, at least one of forming an emission layer or forming an electron transport region includes forming a sub-layer multiple times, and the forming the sub-layer includes providing a preliminary sub-layer and drying the preliminary sub-layer.

This application claims priority to Korean Patent Application No. 10-2025-0014014, filed on Feb. 4, 2025, and all the benefits accruing therefrom under 35 U.S.C. § 119, the content of which in its entirety is herein incorporated by reference.

### BACKGROUND

### 1. Field

The disclosure herein relates to a light-emitting element, an electronic device, and a method for manufacturing the light-emitting element, and more particularly, to a light-emitting element with reduced voids in an electron transport region or an emission layer, an electronic device including the light-emitting element, and a method for manufacturing the light-emitting element.

### 2. Description of the Related Art

Multimedia electronic devices such as televisions, mobile phones, tablet computers, navigation devices, game consoles, or wearable devices may include display modules which display images. The display modules include light-emitting elements, and recently, technologies for the light-emitting elements using quantum dots are being developed.

### SUMMARY

During the manufacture of the light-emitting elements, printing techniques of stacking components of the light-emitting elements layer by layer to manufacture the light-emitting elements may be used. Here, materials are reduced in volume and thus voids are generated during drying electron transport regions or emission layers. When the voids are generated, quality of the light-emitting elements and electronic devices including the same is reduced, for example, diffusion of particles of adjacent layers. Therefore, in recent times, research for reducing the voids in the light-emitting elements is being carried out.

The disclosure provides a light-emitting element with reduced voids and an electronic device including the light-emitting element.

The disclosure also provides a method for manufacturing a light-emitting element with reduced voids.

An embodiment of the inventive concept provides a method for manufacturing a light-emitting element, the method including forming a hole transport region on a first electrode, forming an emission layer including a quantum dot on the hole transport region, forming an electron transport region on the emission layer, and forming a second electrode on the electron transport region. At least one of the forming the emission layer or the forming the electron transport region includes forming a sub-layer multiple times, and the forming the sub-layer includes providing a preliminary sub-layer and drying the preliminary sub-layer.

In an embodiment, the preliminary sub-layer may be provided through inkjet printing.

In an embodiment, each of a plurality of sub-layers formed by repeating the forming the sub-layer multiple times may be an organic/inorganic composite layer.

In an embodiment, the forming the sub-layer may be repeated two to five times.

In an embodiment, preliminary sub-layers provided in the performing the forming the sub-layer multiple times may have same materials as each other.

In an embodiment, a plurality of sub-layers formed by repeating the forming the sub-layer multiple times may have same thicknesses as each other.

In an embodiment, the method may further include forming a block layer before at least one of the forming the emission layer, the forming the electron transport region, or the forming the second electrode.

In an embodiment of the inventive concept, a light-emitting element includes a first electrode, a hole transport region disposed on the first electrode, an emission layer disposed on the hole transport region and including a quantum dot, an electron transport region disposed on the emission layer, and a second electrode disposed on the electron transport region. At least one of the emission layer or the electron transport region includes a plurality of sub-layers divided in a thickness direction, and an H concentration measured along the thickness direction of the plurality of sub-layers may have a local minimum value or a local maximum value at an interface between the plurality of sub-layers.

In an embodiment, each of the plurality of sub-layers may be an organic/inorganic composite layer.

In an embodiment, the plurality of sub-layers may have same thicknesses as each other.

In an embodiment, the plurality of sub-layers may be two to five in number.

In an embodiment, a void may be defined in each of the plurality of sub-layers, and a length of the void in the thickness direction of the plurality of sub-layers may be equal to or less than a thickness of each of the plurality of sub-layers.

In an embodiment, a void may be defined in each of the plurality of sub-layers, and the void may not be connected to a void of a neighboring (adjacent) sub-layer of the plurality of sub-layers.

In an embodiment, the light-emitting element may further include a block layer directly disposed on at least one of a top surface of the emission layer, a bottom surface of the emission layer, a top surface of the electron transport region, or a bottom surface of the electron transport region.

In an embodiment, the plurality of sub-layers may each independently further include at least one of Al₂O₃, TiO₂, SiO₂, BaSO₄, Ta₂O₅, PbCl₂, PbBr₂, PbI₂, indium tin oxide (“ITO”), Ag, ZnO, SnCl₂, SnBr₂, SnI₂, SnO, polyvinylpyrrolidone (“PVP”), or polymethyl methacrylate (“PMMA”).

In an embodiment of the inventive concept, an electronic device includes a display device including a display module which displays an image, and the display module includes a plurality of light-emitting elements. Each of the plurality of light-emitting elements includes a first electrode, a hole transport region disposed on the first electrode, an emission layer disposed on the hole transport region and including a quantum dot, an electron transport region disposed on the emission layer, and a second electrode disposed on the electron transport region. At least one of the emission layer or the electron transport region includes a plurality of sub-layers divided in a thickness direction, and an H concentration measured along the thickness direction of the plurality of sub-layers has a local minimum value or a local maximum value at an interface between the plurality of sub-layers.

In an embodiment, each of the plurality of sub-layers may be an organic/inorganic composite layer.

In an embodiment, the plurality of sub-layers may be two to five in number.

In an embodiment, the electronic device may further include at least one of a processor, a memory, or a power module.

In an embodiment, the electronic device may include the display module and be a television, a monitor, an outdoor billboard, a personal computer, a notebook computer, a personal digital assistant, a vehicle device, a game console, a smartphone, a tablet computer, a smartwatch, or a camera.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a block diagram of an embodiment of an electronic device;

FIG. 1B illustrates schematic views of embodiments of electronic devices;

FIG. 2 is a perspective view of an embodiment of an electronic device;

FIG. 3 is a perspective view of an embodiment of a display module;

FIG. 4 is a cross-sectional view of an embodiment of a display module;

FIG. 5 is a cross-sectional view of an embodiment of a display module;

FIG. 6 is a cross-sectional view of an embodiment of a light-emitting element;

FIG. 7 is a cross-sectional view of an embodiment of a light-emitting element;

FIG. 8 is a cross-sectional view of an embodiment of a light-emitting element;

FIG. 9 is a cross-sectional view of an embodiment of a light-emitting element;

FIG. 10 is a cross-sectional view of an embodiment of a light-emitting element;

FIG. 11 is a cross-sectional view of an embodiment of a light-emitting element;

FIG. 12 is a cross-sectional view of an embodiment of a light-emitting element;

FIG. 13 is a flowchart illustrating an embodiment of a method for manufacturing a light-emitting element;

FIG. 14 is a flowchart illustrating an embodiment of a portion of a method for manufacturing a light-emitting element; and

FIG. 15 is a flowchart illustrating an embodiment of a portion of a method for manufacturing a light-emitting element.

### DETAILED DESCRIPTION

The inventive concept may be modified in various forms, and particular embodiments thereof will be illustrated in the drawings and described herein in detail. The inventive concept should not be construed as limited to the embodiments set forth herein. Rather, these embodiments are provided so that this disclosure will be thorough and complete, and will fully convey the scope of the inventive concept to those skilled in the art.

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. The term “and/or” includes one or more combinations which may be defined by relevant elements.

It will be understood that, although the terms “first”, “second”, etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the inventive concept. Similarly, a second element, component, region, layer or section could be termed a first element, component, region, layer or section. The singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

As used herein, “being directly disposed” may mean that there is no additional layer, film, region, plate or the like between a part such as a layer, film, region, plate or the like and another part. For example, “being directly disposed” may mean that two layers or two members are disposed with no additional member such as an adhesive member.

In this specification, “a region/portion corresponding to another region/portion” means that the regions/portions “overlap each other”, but is not limited to the meaning that the regions/portions have the same surface area and/or the same shape. In addition, in this specification, “a region/portion overlapping another region/portion” means that the regions/portions overlap each other when viewed on a plane, and includes a case in which the region/portion at least partially overlaps the other region/portion on the plane.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a light-emitting element in an embodiment, an electronic device in an embodiment, and a method for manufacturing the light-emitting element in an embodiment will be described with reference to the drawings.

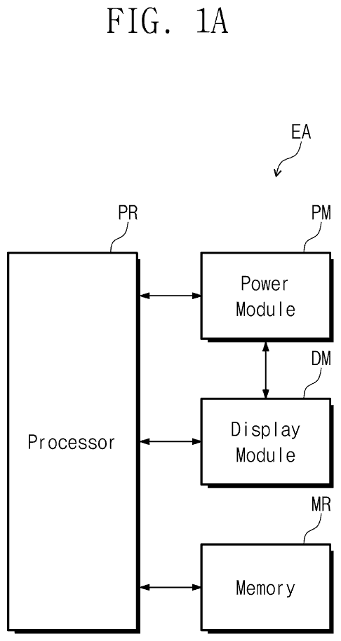

FIG. 1A is a block diagram of an embodiment of an electronic device. Referring to FIG. 1A, an electronic device EA in an embodiment may include a display module DM, a processor PR, a memory MR, and a power module PM.

The processor PR may include at least one of a central processing unit (“CPU”), an application processor (“AP”), a graphic processing unit (“GPU”), a communication processor (“CP”), an image signal processor (“ISP”), or a controller.

The memory MR may store data information desired for an operation of the processor PR or the display module DM. When the processor PR executes an application stored in the memory MR, an image data signal and/or an input control signal may be transmitted to the display module DM, and the display module DM may process the received signal and output image information through a display screen.

The power module PM may include a power supply module such as a power adapter or a battery device, and a power conversion module which converts the power supplied by the power supply module and generates power desired for an operation of the electronic device EA.

At least one of the components of the electronic device EA described above may be included in a display device. In addition, some of individual modules included as functional in one module may be included in the display device, and others may be provided separately from the display device. In an embodiment, the display device may include the display module DM in an embodiment to be described later, for example. The processor PR, the display module DM, and the power module PM may be provided not in the display device but in another type of device in the electronic device EA.

FIG. 1B illustrates schematic views of embodiments of electronic devices.

Referring to FIG. 1B, various electronic devices in embodiments, to which a display device is applied, may include not only an electronic device for image display, e.g., a smartphone EA_1a, a tablet PC EA_1b, a laptop computer EA_1c, television (“TV”) EA_1d, and a monitor for a desk computer EA_1e, but also a wearable electronic device including a display module, e.g., smart glasses EA_2a, a head mounted display EA_2b, and a smart watch EA_2c, and a vehicle electronic device EA_3 including a display module, e.g., a vehicle instrument panel, a center fascia, a center information display (“CID”) disposed on a dashboard, and a room mirror display.

The display device in an embodiment may be applied to various electronic devices. The electronic device in an embodiment may further include a module or device having other additional functions, in addition to the display device.

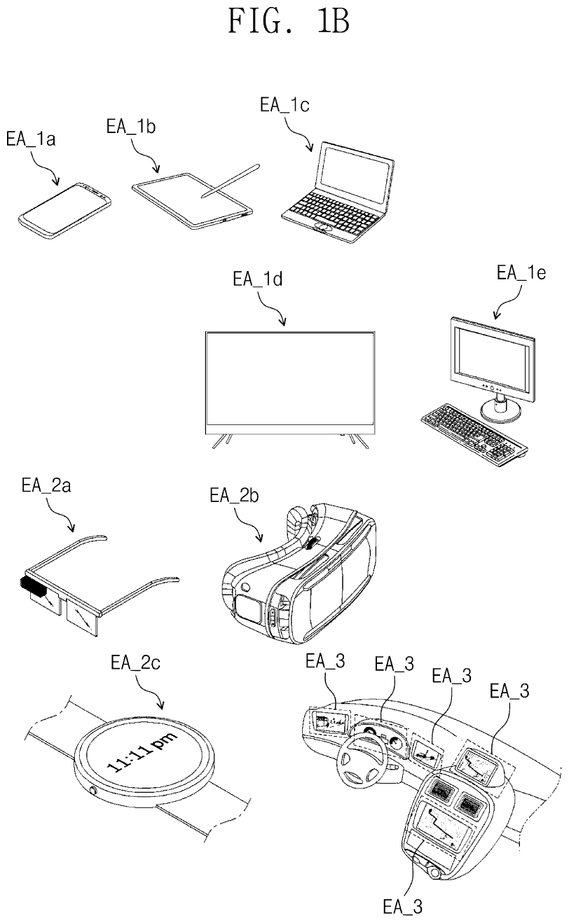

FIG. 2 is a perspective view illustrating an embodiment of an electronic device.

An electronic device EA in an embodiment may include a display device DD which displays an image through a display surface EA-IS. The display device DD may be accommodated and disposed in a housing HAU. The electronic device EA may include the display device DD and a controller which controls an operation of the display device DD.

The display surface EA-IS of the electronic device EA may have a quadrangular shape, e.g., rectangular shape having long sides extending in a first direction DR1 and short sides extending in a second direction DR2 crossing the first direction DR1 when viewed in a plan view. However, the display surface EA-IS is not limited thereto and may have various shapes such as a circular shape and a polygonal shape.

As used herein, a third direction DR3 may be defined as a direction substantially perpendicular to a plane defined by the first direction DR1 and the second direction DR2. A front surface (or top surface) and a rear surface (or bottom surface) of each of members, which constitute the electronic device EA, may oppose each other in the third direction DR3, and a normal direction to each of the front surface and the rear surface may be substantially parallel to the third direction DR3. A separation distance between the front surface and the rear surface, which is defined along the third direction DR3, may correspond to a thickness of the member.

As used herein, the term “in a plan view” may be defined as being in a state when viewed in the third direction DR3. That is, “in a plan view” may be described on the basis of a plane defined by the first direction DR1 and the second direction DR2 together. The term “in a cross-section” used herein may be defined as being in a state when viewed in the first direction DR1 or the second direction DR2. Directions indicated by the first to third directions DR1, DR2 and DR3 are relative concepts and may be changed to other directions.

FIG. 2 illustrates a tablet terminal in an embodiment of the electronic device EA. Electronic modules, a camera module, a power module, or the like, which are disposed (e.g., mounted) on a main board, may be disposed together with a display device DD in a bracket/a housing HAU or the like, thereby constituting the tablet terminal. An embodiment is not limited thereto, and the display device DD and a display module in an embodiment, described later, may be applied to large-sized electronic devices such as television, monitor, or outdoor billboard, and also relatively small and medium-sized electronic devices such as personal computer, notebook computer, personal digital assistant, vehicle navigation unit, game console, smartphone, tablet computer, smart watch, and camera. These are just provided as embodiments, and the display device DD in an embodiment may be adopted as other electronic devices unless departing from the inventive concept. The electronic device EA including the display device DD may be also referred to as a display device.

In an embodiment, the electronic device EA including the display device DD having a flat display surface is illustrated, but the disclosure is not limited thereto. The electronic device EA may include a curved display surface or a three-dimensional display surface. In an embodiment, the three-dimensional display surface may include a plurality of display areas oriented in different directions and include a bent display surface, for example. The electronic device EA in the illustrative embodiment may be a flexible electronic device. The flexible electronic device may be a foldable electronic device capable of being folded.

As illustrated in FIG. 2, the display surface ED-IS includes an active area AA on which an image is displayed, and a bezel area NAA next (adjacent) to the active area AA. The bezel area NAA is an area on which an image is not displayed. FIG. 2 illustrates icon images as one embodiment of the image. The active area AA may be also referred to as a display area of the display device DD, and the bezel area NAA may be also referred to as a non-display area of the display device DD.

As illustrated in FIG. 2, the active area AA may have a substantially quadrangular shape, e.g., rectangular shape. The “substantially rectangular shape” includes not only a rectangular shape in terms of mathematics, but also a rectangular shape in which not a vertex but a curved boundary is defined on a vertex area (or corner area).

The bezel area NAA may surround the active area AA. However, the shape of the bezel area NAA is not limited thereto and may be changed. In an embodiment, the bezel area NAA may be disposed at only one side of the active area AA, for example.

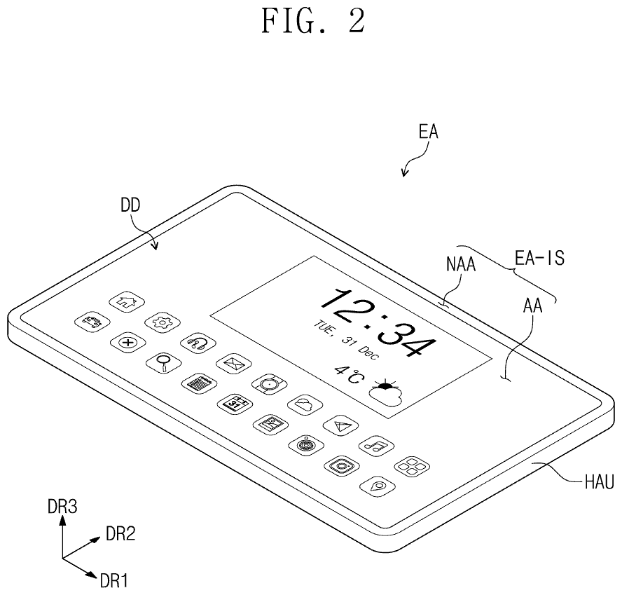

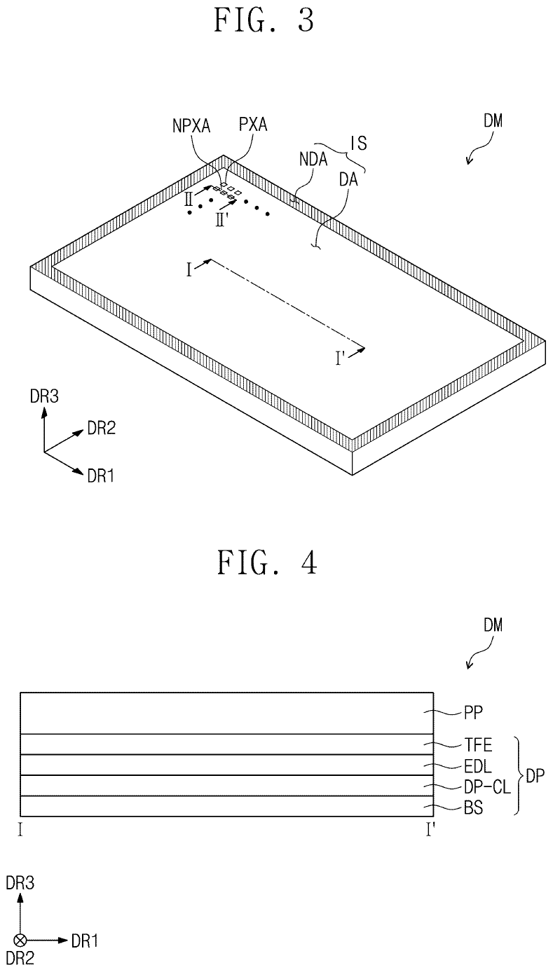

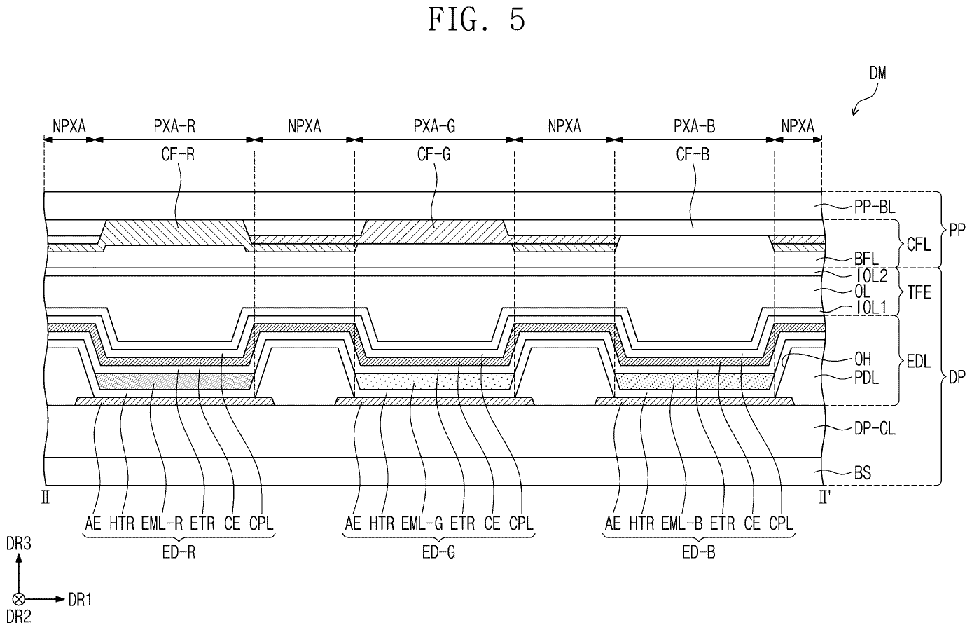

FIG. 3 is a perspective view of an embodiment of a display module according to the inventive concept. FIG. 4 is a cross-sectional view of an embodiment of the display module. FIG. 5 is a cross-sectional view illustrating an embodiment of the display module in more detail. FIG. 4 may be a cross-sectional view corresponding to line I-I′ in FIG. 3, and FIG. 5 may be a cross-sectional view corresponding to line II-II′ in FIG. 3. A display module DM in an embodiment described with reference to FIG. 3 or the like may be included in the display device DD illustrated in FIG. 2 or the like.

Referring to FIG. 3, the display module DM may include a display surface IS, and the display module DM may display an image through the display surface IS. The display surface IS of the display module DM may correspond to a display surface EA-IS of an electronic device EA.

The display surface IS may include a display area DA and a non-display area NDA. A plurality of pixel areas PXA may be disposed in the display area DA. A peripheral area NPXA is disposed around the pixel areas PXA. The pixel areas PXA may be also referred to as emission areas, and the peripheral area NPXA may be also referred to as a non-emission area.

The pixel areas may not be disposed in the non-display area NDA of the display surface IS, and the non-display area NDA may surround the display area DA. However, the inventive concept is not limited thereto, and in an embodiment of the inventive concept, the non-display area NDA may be omitted or be disposed at only one side of the display area DA.

Referring to FIGS. 4 and 5, the display module DM in an embodiment may include a display panel DP. The display panel DP may be a component that substantially generates image data. The display panel DP in an embodiment may be a component that is included in the electronic device EA in an embodiment (refer to FIG. 2) and displays an image. The display panel DP in an embodiment may be an emissive display panel. In an embodiment, the display panel DP may include an inorganic luminous body such as quantum dot.

The display panel DP may include a base layer BS, a circuit layer DP-CL, a display layer EDL, and an encapsulation layer TFE which are stacked in sequence in the third direction (also referred to as a third directional axis) DR3.

The display layer EDL may include light-emitting elements ED-R, ED-G and ED-B. The plurality of pixel areas PXA may be areas which emit light generated from the light-emitting elements ED-R, ED-G and ED-B, respectively.

The encapsulation layer TFE may be directly disposed on the display layer EDL. The encapsulation layer TFE may cover the light-emitting elements ED-R, ED-G and ED-B of the display layer EDL.

The display module DM in an embodiment may further include an optical member PP. The optical member PP may be disposed on the display panel DP. The optical structure layer PP may be disposed on the display panel DP and control reflective light from the display panel DP, caused by external light.

The display module DM in an embodiment may include the plurality of pixel areas PXA repeatedly disposed over the display area DD. The pixel areas PXA in the display module DM in an embodiment may be arranged in the form of a stripe in a plan view. Referring to FIG. 3, the plurality of pixel areas PXA may be arranged along the first direction (also referred to as a first directional axis) DR1 or the first direction (also referred to as a second directional axis) DR2. However, the disclosure is not limited thereto, and an arrangement shape of the pixel areas PXA may include a PenTile (PENTILE™) arrangement shape, or a diamond (Diamond Pixel™) arrangement shape.

In addition, although the pixel areas PXA, all of which have similar surface areas in a plan view, are illustrated in FIG. 3 or the like, the disclosure is not limited thereto, and the surface areas of the pixel areas PXA in a plan view may be different according to wavelength regions of the emitted light.

Referring to FIGS. 3 and 5, the pixel areas PXA may include first to third pixel areas PXA-R, PXA-G and PXA-B. In the display module DM in an embodiment, the first to third pixel areas PXA-R, PXA-G and PXA-B may be areas which are separated from each other in a plan view and emit light in different wavelength regions.

In addition, the display module DM in an embodiment may include a peripheral area NPXA disposed around the first to third pixel areas PXA-R, PXA-G and PXA-B. The peripheral area NPXA sets a boundary between the first to third pixel areas PXA-R, PXA-G and PXA-B. The peripheral area NPXA may surround each of the first to third pixel areas PXA-R, PXA-G and PXA-B. A structure, e.g., a pixel defining film PDL, which prevents color combination between the first to third pixel areas PXA-R, PXA-G and PXA-B may be arranged in the peripheral area NPXA to overlap the peripheral area NPXA.

The first to third pixel areas PXA-R, PXA-G and PXA-B may be areas divided by the pixel defining film PDL. The peripheral area NPXA may be an area which is disposed between neighboring areas of the first to third pixel areas PXA-R, PXA-G and PXA-B, and corresponds to the pixel defining film PDL.

The first to third pixel areas PXA-R, PXA-G and PXA-B may be areas which emit light generated from the first to third light-emitting elements ED-R, ED-G and ED-B, respectively. The first to third pixel areas PXA-R, PXA-G and PXA-B may be spaced apart from each other in a plan view.

The pixel defining film PDL may separate the first to third light-emitting elements ED-R, ED-G and ED-B from each other. Emission layers EML-R, EML-G and EML-B of the first to third light-emitting elements ED-R, ED-G and ED-B may be each disposed within a pixel opening area OH defined in the pixel defining film PDL, and be separated from each other.

The pixel defining film PDL may include a polymer resin. In an embodiment, the pixel defining film PDL may include a polyacrylate-based resin or a polyimide-based resin, for example. The pixel defining film PDL may further include an inorganic material in addition to the polymer resin. The pixel defining film PDL may include a light-absorbing material, or include a black pigment or a black dye. The pixel defining film PDL including the black pigment or the black dye may be embodied as a black pixel defining film. A carbon black or the like may be used as the black pigment or the black dye in formation of the pixel defining film PDL, but the disclosure is not limited thereto.

The pixel defining film PDL may include an inorganic material. In an embodiment, the pixel defining film PDL may include an inorganic material such as silicon nitride (SiNₓ), silicon oxide (SiOₓ), or silicon oxynitride (SiOₓN_{y}), for example.

The first to third pixel areas PXA-R, PXA-G and PXA-B may be divided according to colors of the light generated from the first to third light-emitting elements ED-R, ED-G and ED-B. In an embodiment, in the display module DM in an embodiment, the first pixel area PXA-R may correspond to a red emission area, the second pixel area PXA-G may correspond to a green emission area, and the third pixel area PXA-B may correspond to a blue emission area, for example.

In the display module DM in an embodiment, the light-emitting elements ED-R, ED-G and ED-B may emit light in different wavelength regions. In an embodiment, the first light-emitting element ED-R may correspond to a red light-emitting element that emits red light, the second light-emitting element ED-G may correspond to a green light-emitting element that emits green light, and the third light-emitting element ED-B may correspond to a blue light-emitting element that emits blue light, for example.

Although three pixel areas PXA-R, PXA-G and PXA-B separated from each other are illustrated in FIG. 5 or the like, the disclosure is not limited thereto, and the display module DM in an embodiment may include four or more emission areas having different luminescent properties.

In the display panel DP, the base layer BS may be a member that provides a base surface on which the display layer EDL and the circuit layer DP-CL are disposed. The base layer BS may be a glass substrate, a metal substrate, a plastic substrate, or the like. However, the disclosure is not limited thereto, and the base layer BS may be an inorganic layer, an organic layer, or a composite material layer.

In an embodiment, the circuit layer DP-CL may be disposed on the base layer BS, and the circuit layer DP-CL may include a plurality of transistors (not illustrated). The transistors (not illustrated) may each include a control electrode, an input electrode, and an output electrode. In an embodiment, the circuit layer DP-CL may include a switching transistor and a driving transistor each for driving the light-emitting elements ED-R, ED-G and ED-B of the display layer EDL, for example.

The encapsulation layer TFE may cover the light-emitting elements ED-R, ED-G and ED-B. The encapsulation layer TFE may seal the display layer EDL. The encapsulation layer TFE may be a thin-film encapsulation layer. The encapsulation layer TFE may be one in which a plurality of layers are stacked.

The encapsulation layer TFE in an embodiment may include at least one inorganic film (hereinafter referred to as an inorganic encapsulation film) and at least one organic film (hereinafter referred to as an organic encapsulation film). In an embodiment, the encapsulation layer TFE may include a first inorganic encapsulation film IOL1, an organic encapsulation film OL, and a second inorganic encapsulation film IOL2 which are stacked in sequence on the display layer EDL.

The inorganic encapsulation films IOL1 and IOL2 protect the display layer EDL from moisture/oxygen, and the organic encapsulation film OL protects the display layer EDL from foreign matter such as dust particles. The inorganic encapsulation films IOL1 and IOL2 may include silicon nitride, silicon oxynitride, silicon oxide, titanium oxide, or aluminum oxide, but are not particularly limited thereto.

The display module DM in an embodiment may further include the optical member PP. The optical member PP may be a reflection reduction layer which reduces reflectance caused by external light. In an embodiment, the optical member PP may include a polarizing film including a retarder and/or a polarizer, a plurality of reflective layers that cause the reflective light to destructively interfere with each other, or color filters arranged to correspond to pixel arrangement and emissive colors of the display panel DP, for example. In an alternative embodiment, the optical member PP may be omitted.

Referring to FIG. 5, in an embodiment, the optical member PP may include a base substrate PP-BL and a color filter layer CFL.

The base substrate PP-BL may be a member which provides a base surface on which the color filter layer CFL or the like is disposed. The base substrate PP-BL may be a glass substrate, a metal substrate, a plastic substrate, or the like. However, the disclosure is not limited thereto, and the base substrate PP-BL may be an inorganic layer, an organic layer, or a composite material layer.

In an embodiment, the color filter layer CFL may include first to third color filters CF-R, CF-G and CF-B. The first to third color filters CF-R, CF-G and CF-B may be arranged to correspond to the first to third light-emitting elements ED-R, ED-G and ED-B, respectively. In an embodiment, the first color filter CF-R may be a red filter, the second color filter CF-G may be a green filter, and the third color filter CF-B may be a blue filter, for example. The first to third color filters CF-R, CF-G and CF-B may be arranged to correspond to the first to third pixel areas PXA-R, PXA-G and PXA-B, respectively.

The plurality of color filters CF-R, CF-G and CF-B which filter different light may be arranged to overlap each other in an area corresponding to the peripheral area NPXA disposed between the pixel areas PXA-R, PXA-G and PXA-B. The plurality of color filters CF-B, CF-G and CF-R may be arranged to overlap each other in the third direction DR3 that is a thickness direction, thereby defining a boundary between pixel areas next (adjacent) to each other among the pixel areas PXA-R, PXA-G and PXA-B. Accordingly, an effect of blocking external light may be increased to have the same function as a black matrix. A structure in which the plurality of color filters CF-B, CF-G and CF-R overlap each other may have a function to prevent color combination.

Each of the first to third color filters CF-R, CF-G and CF-B may include a polymer photosensitive resin and a pigment or a dye. The first color filter CF-R may include a red pigment or a red dye, the second color filter CF-G may include a green pigment or a green dye, and the third color filter CF-B may include a blue pigment or a blue dye. However, the disclosure is not limited thereto, and the third color filter CF-B may not include a pigment or a dye. The third color filter CF-B may include a polymer photosensitive resin but not include a pigment or a dye. The third color filter CF-B may be transparent. The third color filter CF-B may include a transparent photosensitive resin.

The color filter layer CFL may further include a buffer layer BFL. In an embodiment, the buffer layer BFL may be a protective layer which protects the first to third color filters CF-R, CF-G and CF-B, for example. The buffer layer BFL may be an inorganic material layer including at least one inorganic material of silicon nitride, silicon oxide, and silicon oxynitride. The buffer layer BFL may have include a single layer or a plurality of layers.

In addition, the first color filter CF-R and the second color filter CF-G may be yellow filters. The first color filter CF-R and the second color filter CF-G may not be separated from each other but be provided as one body.

Although not illustrated, the color filter layer CFL may further include a light block part (not illustrated). The light block part may be a black matrix. The light block part may include an organic light-blocking material or an inorganic light-blocking material each including a black pigment or a black dye. The light block part may prevent light leakage, and define a boundary between color filters next (adjacent) to each other among the color filters CF-R, CF-G and CF-B.

In an alternative embodiment, unlike embodiments illustrated in FIG. 5 or the like, the optical member PP of the display module DM in an embodiment may not include the color filter layer CFL.

In the display module DM in an embodiment, each of the first to third light-emitting elements ED-R, ED-G and ED-B may include a first electrode AE, a hole transport region HTR, an emission layer EML-R, EML-G or EML-B, an electron transport region ETR, and a second electrode CE. In addition, each of the light-emitting elements ED-R, ED-G and ED-B may include a capping layer CPL disposed on the second electrode CE.

The first electrode AE may be exposed in the pixel opening area OH of the pixel defining film PDL.

The second electrode CE may be disposed on the first electrode AE. The second electrode CE may be disposed to oppose the first electrode AE with the emission layers EML-R, EML-G and EML-B therebetween. The second electrode CE may be a cathode or an anode. In an embodiment, when the first electrode AE is an anode, the second electrode CE may be a cathode, and when the first electrode AE is a cathode, the second electrode CE may be an anode. The second electrode CE may be a common electrode. The second electrode CE may be a transmissive electrode, a semi-transmissive electrode, or a reflective electrode.

The first electrode AE may be divided and arranged so as to correspond to each of the pixel areas PXA-R, PXA-G and PXA-B. The second electrode CE may be provided as a common layer to the entirety of the pixel areas PXA-R, PXA-G and PXA-B.

The hole transport region HTR may be disposed between the first electrode AE and the emission layers EML-R, EML-G and EML-B, and the electron transport region ETR may be disposed between the emission layers EML-R, EML-G and EML-B and the second electrode CE. Referring to FIG. 5, each of the hole transport region HTR and the electron transport region ETR may be provided as a common layer to the entirety of the pixel areas PXA-R, PXA-G and PXA-B. However, the disclosure is not limited thereto, and the hole transport region HTR and the electron transport region ETR may be each independently divided and arranged so as to correspond to each of the pixel areas PXA-R, PXA-G and PXA-B.

In an embodiment illustrated in FIG. 5, the emission layers EML-R, EML-G and EML-B of the first to third light-emitting elements ED-R, ED-G and ED-B may be each disposed within the pixel opening area OH. That is, in an embodiment, the emission layers EML-R, EML-G and EML-B may be divided and arranged so as to correspond to the pixel areas PXA-R, PXA-G and PXA-B, respectively. In an embodiment, the emission layers EML-R, EML-G and EML-B may include quantum dots.

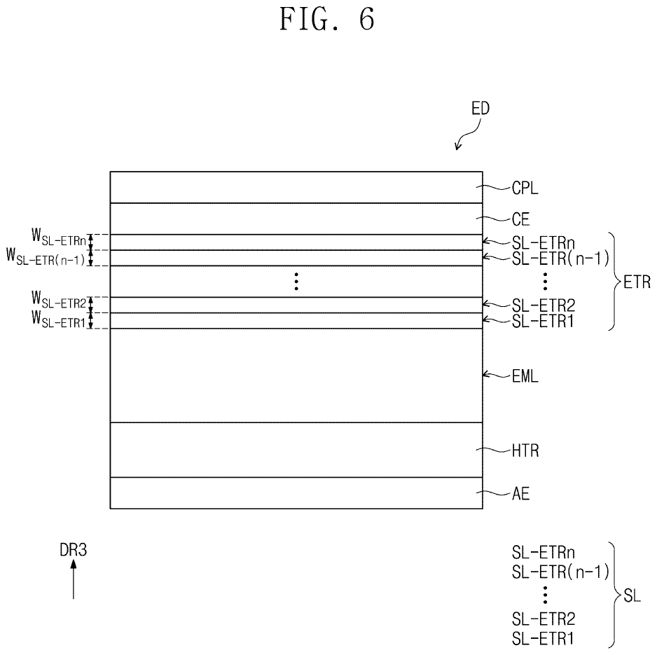

In an embodiment, each of the first to third light-emitting elements ED-R, ED-G and ED-B may further include the capping layer CPL. The capping layer CPL may be disposed on the second electrode CE. The capping layer CPL may have a multilayer structure or a single-layer structure. Referring to FIG. 6, in the display module DM in an embodiment, the capping layer CPL may be provided as a common layer to the entirety of the pixel areas PXA-R, PXA-G and PXA-B.

In each of the first to third light-emitting elements ED-R, ED-G and ED-B illustrated in FIG. 5 or the like, a stacked structure of the hole transport region HTR, the emission layers EML-R, EML-G and EML-B, the electron transport region ETR, disposed between the first electrode AE and the second electrode CE, may be also referred to as one emission unit. Although FIG. 5 or the like illustrate a case in which each of the first to third light-emitting elements ED-R, ED-G and ED-B includes one emission unit, the disclosure is not limited thereto, and in an embodiment, the first to third light-emitting elements ED-R, ED-G and ED-B may be each independently include a plurality of emission units stacked between the first electrode AE and the second electrode CE in the thickness direction. In an embodiment, the first to third light-emitting elements ED-R, ED-G and ED-B may be each independently a tandem light-emitting element including a plurality of emission layers stacked in the thickness direction, for example.

FIGS. 6 to 9 are each a cross-sectional view of an embodiment of a light-emitting element. In an embodiment, FIGS. 6 to 9 each illustrate a structure of one of a plurality of light-emitting elements included in a display panel DM. In an embodiment, FIGS. 6 to 9 illustrate cross-sectional views of light-emitting elements ED, ED-a, ED-b and ED-c representing the first to third light-emitting elements ED-R, ED-G and ED-B included in the display layer EDL illustrated in FIG. 5.

Referring to FIG. 6, the light-emitting element ED in an embodiment may include a first electrode AE, a second electrode CE facing the first electrode AE, and a hole transport region HTR, an emission layer EML, and an electron transport region ETR which are disposed between the first electrode AE and the second electrode CE. In addition, the light-emitting element ED may further include a capping layer CPL disposed on the second electrode CE.

The first electrode AE has conductivity. The first electrode AE may include a metal material, a metal alloy, or a conductive compound. The first electrode AE may be an anode or a cathode. The first electrode AE may also be a pixel electrode. The first electrode AE may be a transmissive electrode, a semi-transmissive electrode, or a reflective electrode. The first electrode AE may include at least one selected from Ag, Mg, Cu, Al, Pt, Pd, Au, Ni, Nd, Ir, Cr, Li, Ca, LiF, Mo, Ti, W, In, Sn, and Zn, a compound of two or more selected therefrom, a combination of two or more selected therefrom, or an oxide thereof.

When the first electrode AE is a transmissive electrode, the first electrode AE may include a transparent metal oxide, e.g., indium tin oxide (“ITO”), indium zinc oxide (“IZO”), zinc oxide (ZnO), indium tin zinc oxide (“ITZO”), or the like. When the first electrode AE is a semi-transmissive electrode or a reflective electrode, the first electrode AE may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or combination thereof (e.g., a combination of Ag and Mg). In an alternative embodiment, the first electrode AE may have a multilayer structure including a reflective film or a semi-transmissive film, each of which includes the foregoing material, and a transparent conductive film which includes ITO, IZO, zinc oxide (ZnO), ITZO, or the like. In an embodiment, the first electrode AE may have a three-layer structure of ITO/Ag/ITO, for example, but is not limited thereto.

The second electrode CE may be a transmissive electrode, a semi-transmissive electrode, or a reflective electrode. When the second electrode CE is a transmissive electrode, the second electrode CE may include a transparent metal oxide, e.g., ITO, IZO, zinc oxide (ZnO), ITZO, or the like.

When the second electrode CE is a semi-transmissive electrode or a reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, or a compound or combination thereof (e.g., AgMg, AgYb or MgYb). In an alternative embodiment, the second electrode CE may have a multilayer structure including a reflective film or a semi-transmissive film, each of which includes the foregoing material, and a transparent conductive film which includes ITO, IZO, zinc oxide (ZnO), ITZO, or the like. In an embodiment, the second electrode CE may include the foregoing metal material, a combination of two or more metal materials selected from the foregoing metal materials, oxides of the foregoing metal materials, or the like, for example.

In an embodiment, the capping layer CPL may have a multilayer structure or a single-layer structure.

In an embodiment, the capping layer CPL may be an organic layer or an inorganic layer. In an embodiment, when the capping layer CPL includes an inorganic material, the inorganic material may include an alkaline metal compound such as LiF, an alkaline earth metal compound such as MgF2, SiON, SiNₓ, SiOy, or the like, for example.

In an embodiment, when the capping layer CPL includes an organic material, the organic material may include α-NPD, N,N′-di(naphthalene-1-yl)-N,N′-diphenyl-benzidine (“NPB”), N,N′-bis(3-methylphenyl)-N,N′-diphenyl-[1,1′-biphenyl]-4,4′-diamine (“TPD”), 4,4′,4″-[tris(3-methylphenyl)phenylamino]triphenylamine (“m-MTDATA”), Tris(8-hydroxyquinolinato)aluminum (“Alq₃”), Copper Phthalocyanine (“CuPc”), N4,N4,N4′,N4′-tetra (“biphenyl-4-yl”) biphenyl-4,4′-diamine (“TPD15”), 4,4′,4″-Tris (“carbazol sol-9-yl”)triphenylamine (“TCTA”), or the like, or include an epoxy-based resin, or an acrylate-based resin such as methacrylate, for example. However, the disclosure is not limited thereto, and the capping layer CPL may include at least one of Compounds P1 to P5 as follows.

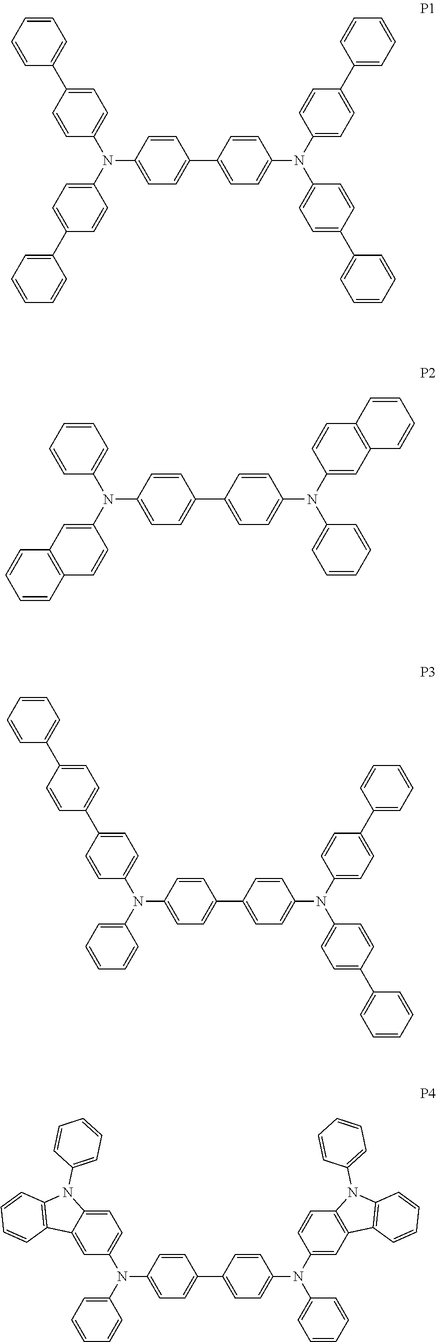 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

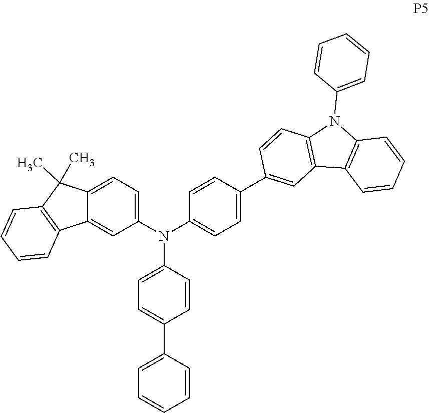 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

The capping layer CPL may have a refractive index of about 1.6 or more. Specifically, the refractive index of the capping layer CPL with respect to light having a wavelength range of about 550 nanometers (nm) to about 660 nm may be 5 about 1.6 or more.

The hole transport region HTR may be disposed between the first electrode AE and the emission layer EML. The hole transport region HTR may include a common hole transport material.

When only the electron transport region ETR is manufactured to include a plurality of sub-layers SL by a method for manufacturing a light-emitting element in an embodiment to be described later, the hole transport region HTR may be formed by a common method. In an embodiment, the hole transport region HTR may be formed using various methods such as a vacuum deposition method, a spin coating method, a cast method, a Langmuir-Blodgett (“LB”) method, an inkjet printing method, a laser printing method, or a laser induced thermal imaging method, for example.

The hole transport region HTR may have a single layer including a single material, a single layer including a plurality of different materials, or a multilayer structure having a plurality of layers including a plurality of different materials from each other. The hole transport region HTR may include at least one of a hole injection layer, a hole transport layer, a buffer layer or an emission auxiliary layer, or an electron blocking layer.

The hole transport region HTR may include a phthalocyanine compound such as copper phthalocyanine, N1,N1′-([1,1′-biphenyl]-4,4′-diyl)bis(N1-phenyl-N4,N4-di-m-tolylbenzene-1,4-diamine) (“DNTPD”), m-MTDATA, 4,4′4″-Tris(N,N-diphenylamino)triphenylamine (“TDATA”), 4,4′,4″-tris[N (2-naphthyl)-N-phenylamino]-triphenylamine (“2-TNATA”), Poly(3,4-ethylenedioxythiophene)/Poly(4-styrenesulfonate) (“PEDOT/PSS”), Polyaniline/Dodecylbenzenesulfonic acid (“PANI/DBSA”), Polyaniline/Camphor sulfonicacid (“PANI/CSA”), Polyaniline/Poly(4-styrenesulfonate) (“PANI/PSS”), NPB, triphenylamine-containing polyetherketone (“TPAPEK”), 4-Isopropyl-4′-methyldiphenyliodonium [Tetrakis(pentafluorophenyl) borate], dipyrazino[2,3-f: 2′,3′-h]dipyrazino[2,3-f: 2′,3′-h]quinoxaline-2,3,6,7,10,11-hexacarbonitrile (“HATCN”), or the like.

The hole transport region HTR may include a carbazole-based derivative such as N-phenyl carbazole or polyvinyl carbazole, a fluorene-based derivative, a triphenylamine-based derivative such as TPD or TCTA, NPB, 4,4′-Cyclohexylidene bis[N,N-bis(4-methylphenyl)benzenamine](“TAPC”), 4,4′-Bis[N,N′-(3-tolyl)amino]-3,3′-dimethylbiphenyl (“HMTPD”), 1,3-Bis(N-carbazolyl)benzene (“mCP”), or the like.

The hole transport region HTR may include 9-(4-tert-Butylphenyl)-3,6-bis(triphenylsilyl)-9H-carbazole (“CzSi”), 9-phenyl-9H-3,9′-bicarbazole (“CCP”), 1,3-bis(1,8-dimethyl-9H-carbazol-9-yl)benzene (“mDCP”), or the like.

The emission layer EML includes a quantum dot. The quantum dot used herein refers to a crystal of a semiconductor compound. The quantum dot may emit light having various emission wavelengths according to a size of the crystal. The quantum dot may emit light having various emission wavelengths by adjusting a ratio of elements in the semiconductor compound.

The quantum dot may have a diameter of about 1 nm to about 10 nm, for example. The quantum dot may be synthesized through a wet chemical process, a metal organic chemical vapor deposition process, a molecular beam epitaxy process, or the like.

Among the quantum dot manufacturing processes, the wet chemical process is a method for mixing an organic solvent and a precursor material and then growing quantum dot particle crystals. When the quantum dot particle crystals grow, the organic solvent may naturally serve as a dispersant coordinated on surfaces of the quantum dot crystals, and control the growth of the particle crystals. Thus, in the wet chemical process, the growth of quantum dot particles may be controlled through a process performed more easily and at lower costs than a vapor deposition process such as metal organic chemical vapor deposition or molecular beam epitaxy.

A core of the quantum dot may include or consist of a Group II-VI compound, a Group III-V compound, a Group III-VI compound, a Group I-III-VI compound, a Group IV-VI compound, a Group IV element, a Group IV compound, or any combinations thereof.

The Group II-VI compound may include or consist of the group consisting of a binary compound selected from the group consisting of CdSe, CdTe, CdS, ZnS, ZnSe, ZnTe, ZnO, HgS, HgSe, HgTe, MgSe, MgS, and any combinations thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and any combinations thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and any combinations thereof. The Group II-VI semiconductor compound may further include a Group I metal and/or a Group IV element. A Group I-II-VI compound may include or consist of CuSnS or CuZnS, and a Group II-IV-VI compound may include or consist of ZnSnS or the like. A Group I-II-IV-VI compound may include or consist of a quaternary compound selected from the group consisting of Cu₂ZnSnS₂, Cu₂ZnSnS₄, Cu₂ZnSnSe₄, Ag₂ZnSnS₂, and any combinations thereof.

The Group III-VI compound may include a binary compound such as In₂S₃ or In₂Se₃, a ternary compound such as InGaS₃ or InGaSe₃, or any combination thereof.

The Group I-III-VI compound may include or consist of a ternary compound selected from the group consisting of AgInS, AgInS₂, CuInS, CuInS₂, AgGaS₂, CuGaS₂, CuGaO₂, AgGaO₂, AgAlO₂, and any combinations thereof, or a quaternary compound such as AgInGaS₂ or CuInGaS₂.

The Group III-V compound may include or consist of the group consisting of a binary compound selected from the group consisting of GaN, GaP, GaAs, GaSb, AlN, AIP, AlAs, AlSb, InN, InP, InAs, InSb, and any combinations thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and any combinations thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and any combinations thereof. The Group III-V compound may further include a Group II metal. In an embodiment, InZnP or the like may be selected as a Group III-II-V compound.

The Group IV-VI compound may include or consist of the group consisting of a binary compound selected from the group consisting of SnS, SnSe, SnTe, PbS, PbSe, PbTe, and any combinations thereof, a ternary compound selected from the group consisting of SnSeS, SnSeTe, SnSTe, PbSeS, PbSeTe, PbSTe, SnPbS, SnPbSe, SnPbTe, and any combinations thereof, and a quaternary compound selected from the group consisting of SnPbSSe, SnPbSeTe, SnPbSTe, and any combinations thereof.

In embodiments, a Group II-IV-V semiconductor compound may include a ternary compound selected from the group consisting of ZnSnP, ZnSnP₂, ZnSnAs₂, ZnGeP₂, ZnGeAs₂, CdSnP₂, and CdGeP₂, and any combinations thereof.

The Group IV element may include or consist of the group consisting of Si, Ge, and any combinations thereof. The Group IV compound may be a binary compound selected from the group consisting of SiC, SiGe, and any combinations thereof.

Each of elements included in a multi-element compound such as a binary compound, a ternary compound, and a quaternary compound, may be present in a particle at a uniform concentration or non-uniform concentration. That is, the representation of a chemical formula representing the quantum dot indicates types of elements included in a quantum dot compound, and ratios of the elements in the compound may be different.

Here, the binary compound, the ternary compound, or the quaternary compound may be present at a uniform concentration in a particle, or may be divided in partially different concentration distributions and present in the same particle. In addition, the quantum dot may have a core/shell structure in which one quantum dot surrounds another quantum dot. In the core/shell structure, the quantum dot may have a concentration gradient in which the concentration of an element present in the shell gradually decreases toward the core.

The shell of the quantum dot may serve as a protective layer for preventing a chemical change of the core to maintain semiconductor characteristics, and/or as a charging layer for imparting electrophoretic characteristics to the quantum dot. The shell may have a single-layer structure or a multilayer structure. In embodiments, the shell of the quantum dot may include a metal or nonmetal oxide, a semiconductor compound, or combinations thereof.

In an embodiment, the metal or nonmetal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, for example, but the inventive concept is not limited thereto.

In addition, embodiments of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like, but the inventive concept is not limited thereto.

In an embodiment, when the quantum dot of the Group III-V compound has a core-shell structure, the quantum dot may include InP or InZnP as the core and ZnSeS as the shell, or have a dual shell structure of ZnSe/ZnS, for example. However, the disclosure is not limited thereto, and the quantum dot may have a combination of the core and the shell, selected from the foregoing semiconductor compounds.

The quantum dot may have a full width of half maximum (“FWHM”) of an emission wavelength spectrum of about 45 nm or less, preferably about 40 nm or less, more preferably about 30 nm or less, and, in this range, color purity or color reproducibility may be improved. Moreover, light emitted through this quantum dot may be emitted in all directions, and thus a wide viewing angle may be improved.

In addition, the form of the quantum dot is a form generally used in this field and is not particularly limited. More specifically, spherical, pyramidal, multi-armed, or cubic nanoparticles, or particles in the form of nanotubes, nanowires, nanofibers, or nanoplate, or the like, may be used.

In the quantum dot, an energy band gap may be adjusted by adjusting the size of the quantum dot or adjusting the ratio of elements in a quantum dot compound, and thus light having various wavelength bands may be obtained from an emission layer including the quantum dot. Thus, the quantum dots (having different sizes or having different ratios of elements in the quantum dot compound) as described above may be used to achieve a light-emitting element that emits light having several wavelengths. Specifically, the size of the quantum dot or the ratio of elements in the quantum dot compound may be selectively adjusted so that red, green and/or blue light are emitted. In addition, the quantum dots may be configured so as to emit white light by combining light of various colors.

When the emission layer EML and/or the electron transport region ETR include the plurality of sub-layers SL to be described later, the plurality of sub-layers may be each an organic/inorganic composite layer. The organic/inorganic composite layer is a layer including a combination of an organic material and an inorganic material. The organic material may include or consist of Alq₃, 2,2′,2″-(1,3,5-Benzinetriyl)-tris(1-phenyl-1-H-benzimidazole) (“TPBi”), Diphenyl-1,10-phenanthroline (“Bathophenanthroline” or “BPhen”), or the like, and the inorganic material may include or consist of ZnO, TiO₂, Cs₂CO₃, or the like. However, the organic material and the inorganic material are not limited thereto.

The electron transport region ETR may be disposed between the emission layer EML and the second electrode CE. The electron transport region ETR may include a common electron transport material.

When only the emission layer EML is manufactured to include the plurality of sub-layers SL by the method for manufacturing the light-emitting element in an embodiment to be described later, the electron transport region ETR may be formed by a common method. In an embodiment, the electron transport region ETR may be formed using various methods such as a vacuum deposition method, a spin coating method, a cast method, an LB method, an inkjet printing method, a laser printing method, or a laser induced thermal imaging method, for example.

The electron transport region ETR may have a single layer including a single material, or a single layer including a plurality of different materials, or a multilayer structure having a plurality of layers including a plurality of different materials from each other. The electron transport region ETR may include an electron transport layer and an electron injection layer which are stacked. In an alternative embodiment, the electron transport region ETR may include at least one of a hole blocking layer, an electron transport layer, a buffer layer, or an electron injection layer.

In an embodiment, the electron transport region ETR may include a metal oxide. The electron transport region ETR may include at least one of types of metal oxides such as Li₂O, BaO, ZnO, ZnMgO, or MgO.

The electron transport region ETR may further include remaining (the other) common electron transport materials. In an embodiment, the electron transport region ETR may include Alq₃, 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzoimidazol-1-yl)phenyl)-9,10-dinaphthylanthracene, 1,3,5-Tri (1-phenyl-1H-benzo[d]imidazol-2-yl)benzene (“TPBi”), 2,9-Dimethyl-4,7-diphenyl-1,10-phenanthroline (“BCP”), Bphen, 3-(4-Biphenylyl)-4-phenyl-5-tert-butylphenyl-1,2,4-triazole (“TAZ”), 4-(Naphthalen-1-yl)-3,5-diphenyl-4H-1,2,4-triazole (“NTAZ”), 2-(4-Biphenylyl)-5-(4-tert-butylphenyl)-1,3,4-oxadiazole (“tBu-PBD”), Bis(2-methyl-8-quinolinolato-N1,O8)-(1,1′-Biphenyl-4-olato)aluminum (“BAlq”), berylliumbis(benzoquinolin-10-olate) (“Bebq₂”), 9,10-di(naphthalene-2-yl) anthracene (“ADN”), 1,3-Bis[3,5-di(pyridin-3-yl)phenyl]benzene (“BmPyPhB”), and any combinations thereof, or 8-hydroxyl-Lithium quinolate (“Liq”) or the like, for example.

In addition, the electron transport region ETR may include a halogenated metal such as LiF, NaCl, CsF, RbCl, RbI, CuI, or KI, a lanthanum group metal such as Yb, or a co-deposition material of the halogenated metal and the lanthanum group metal. In an embodiment, the electron transport region ETR may include KI:Yb, RbI:Yb, LiF:Yb, or the like as a co-deposition material, for example.

The electron transport region ETR may also include a material in which an electron transport material and an insulating organo metal salt are mixed. The organo metal salt may be a material having an energy band gap of about 4 electron-volts (eV) or more. Specifically, the organo metal salt may include metal acetate, metal benzoate, metal acetoacetate, metal acetylacetonate, or metal stearate, for example.

The electron transport region ETR may further include, in addition to the foregoing materials, at least one of BCP, diphenyl(4-(triphenylsilyl)phenyl)phosphine oxide (“TSPO1”), or Bphen, but the disclosure is not limited thereto.

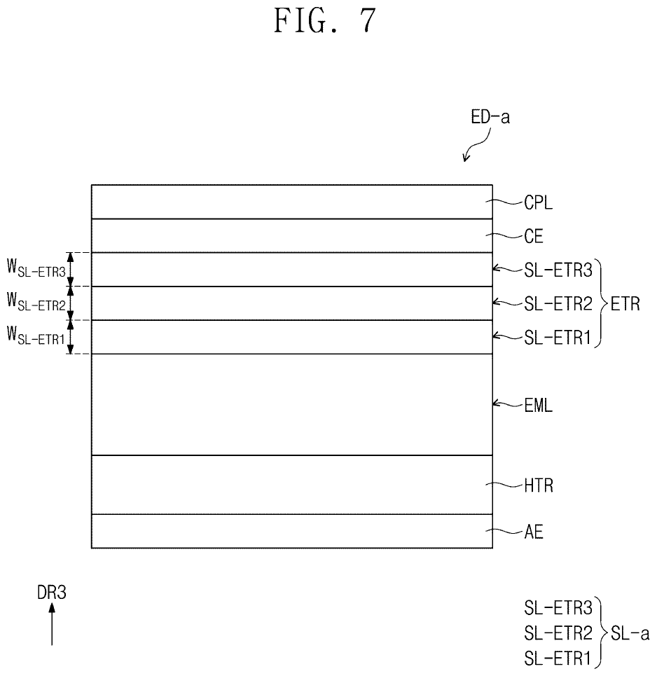

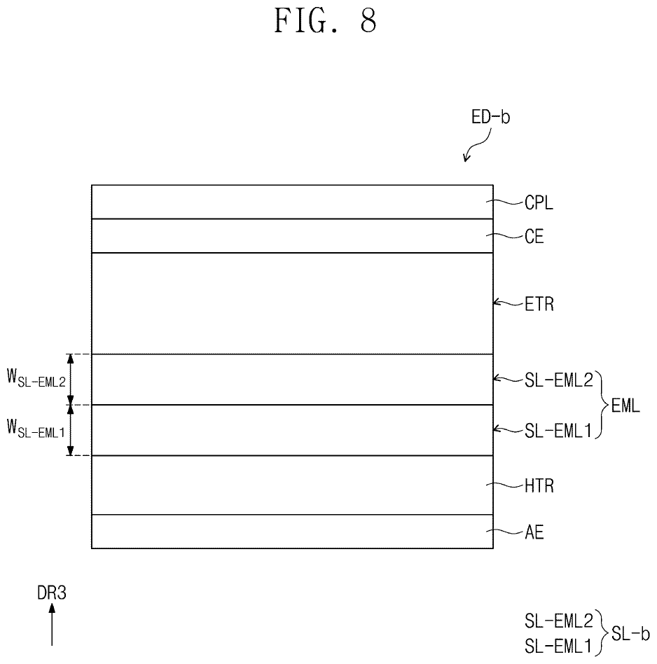

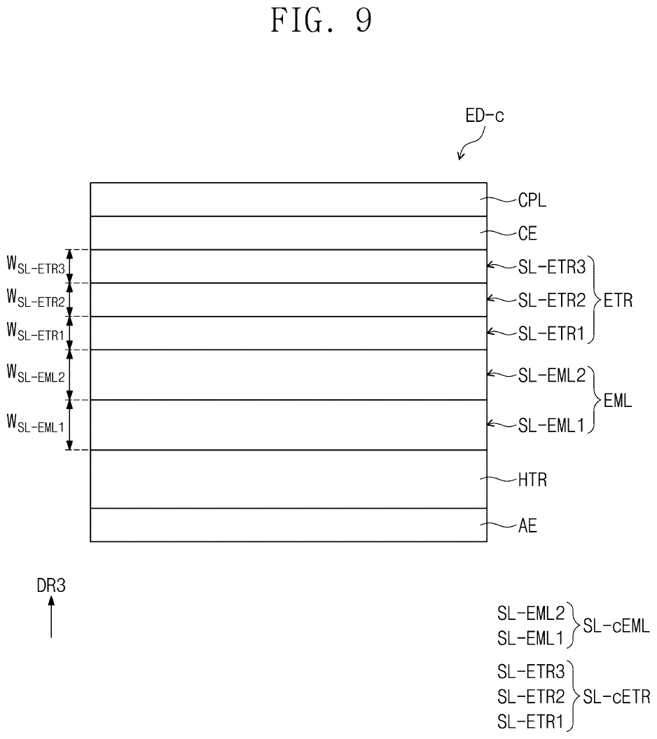

In the light-emitting element ED in an embodiment, at least one of the emission layer EML or the electron transport region ETR includes the plurality of sub-layers SL divided in the thickness direction. FIG. 6 illustrates the electron transport region ETR including the sub-layers SL, which are n in number, divided in the thickness direction. In an embodiment, FIG. 7 illustrates the electron transport region ETR which includes three sub-layers SL-a divided in the thickness direction. In an embodiment, FIG. 8 illustrates the emission layer EML which includes two sub-layers SL-b divided in the thickness direction. In an embodiment, FIG. 9 illustrates the electron transport region ETR which includes three sub-layers SL-a divided in the thickness direction, and the emission layer EML which includes two sub-layers SL-b divided in the thickness direction. However, the disclosure is not limited thereto. An H concentration measured along a thickness direction of the plurality of sub-layers SL have a local minimum value or a local maximum value at an interface between the plurality of sub-layers SL. The “thickness direction” may be the third direction DR3. Thus, even when the plurality of sub-layers SL include or consist of the same material, the sub-layers SL may be divided by the interface between the plurality of sub-layers SL. In an embodiment, when the H concentration is measured along the thickness direction of the plurality of sub-layers SL, the H concentration changes at an interface between a first sub-layer SL-ETR1 and a second sub-layer SL-ETR2, for example. Thus, the H concentration may have the local minimum value or the local maximum value at the interface so that the first sub-layer SL-ETR1 and the second sub-layer SL-ETR2 are divided.

The reason why the H concentration changes at the interface between the sub-layers SL may be that the plurality of sub-layers SL are formed by a discontinuous printing technique. The discontinuous printing technique is a method in which, when the emission layer EML and/or the electron transport region ETR are formed through inkjet printing, providing a preliminary sub-layer and drying the preliminary sub-layer are repeated not once but multiple times to form layers. That is, the reason why the H concentration changes at the interface between the sub-layers SL may be that each of operations of forming sub-layers SL-ETR1 to SL-ETRn (n being a natural number greater than 1) includes the providing of the preliminary sub-layer and the drying of the preliminary sub-layer. In an embodiment, an operation of forming a first sub-layer SL-ETR1 includes providing a first preliminary sub-layer and then drying the first preliminary sub-layer, and during the drying of the first preliminary sub-layer, the H concentration of a top surface of the first preliminary sub-layer may be decreased or increased by evaporation or contamination, for example. Thus, when after the forming of the first sub-layer SL-ETR1, a second preliminary sub-layer is provided on a top surface of the first sub-layer SL-ETR1 and the second preliminary sub-layer is dried to provide a second sub-layer SL-ETR2, the H concentration may have a local minimum value or a local maximum value at an interface between the first sub-layer SL-ETR1 and the second sub-layer SL-ETR2. However, the reason why the H concentration changes at the interface between the sub-layers SL is not limited by the foregoing manufacturing method.

For the same reason, an F concentration may change at the interface between the sub-layers SL. That is, when the F concentration is measured along the thickness direction of the plurality of sub-layers SL, the F concentration may have a local minimum value or a local maximum value at the interface between the plurality of sub-layers SL.

In an embodiment, each of the plurality of sub-layers SL may be an organic/inorganic composite layer. The emission layer EML and/or the electron transport region ETR may be a layer including both an organic material and an inorganic material. In this case, the light-emitting element may exhibit relatively excellent optical properties.

In an embodiment, the plurality of sub-layers SL may have the same thickness. Referring to FIG. 6, when the electron transport region ETR includes the plurality of sub-layers SL, a first thickness W_{SL-ETR1} of the first sub-layer SL-ETR1 through an n-th thickness W_{SL-ETRn} of the n-th sub-layer SL-ETRn may be the same.

Referring to FIG. 7, when the electron transport region ETR includes the plurality of sub-layers SL-a, a first thickness W_{SL-ETR1} of a first sub-layer SL-ETR1, a second thickness W_{SL-ETR2} of a second sub-layer SL-ETR2, and a third thickness W_{SL-ETR3} of a third sub-layer SL-ETR3 may be the same.

Referring to FIG. 8, when the emission layer EML includes the plurality of sub-layers SL-b, a first thickness W_{SL-EML1} of a first sub-layer SL-EML1 and a second thickness W_{SL-EML2} of a second sub-layer SL-EML2 may be the same.

Referring to FIG. 9, when the electron transport region ETR includes a plurality of sub-layers SL-cETR and the emission layer EML also includes a plurality of sub-layers SL-cEML, a first thickness W_{SL-ETR1} of a first sub-layer SL-ETR1, a second thickness W_{SL-ETR2} of a second sub-layer SL-ETR2, and a third thickness WSL-ETR3 of a third sub-layer SL-ETR3 in the electron transport region ETR may be the same, and a first thickness W_{SL-EML1} of a first sub-layer SL-EML1 and a second thickness W_{SL-EML2} of a second sub-layer SL-EML2 in the emission layer EML may be the same. However, the respective thicknesses W_{SL-ETR1}, W_{SL-ETR2} and W_{SL-ETR3} of the sub-layers SL-ETR1, SL-ETR2 and SL-ETR3 in the electron transport region ETR may be the same as or different from the respective thicknesses W_{SL-EML1} and W_{SL-EML2} of the sub-layers in the emission layer EML. When the thicknesses of the plurality of sub-layers SL are the same, the display quality of the light-emitting elements ED, ED-a, ED-b and ED-c may be relatively excellent.

In an embodiment, the plurality of sub-layers SL may be 2 to 5 in number. When the plurality of sub-layers SL is 6 or more in number, the sub-layers SL-ETR1 to SL-ETRn may each have an excessively small thickness and be thus difficult to manufacture in a uniform thickness, and the display quality of the light-emitting element may be reduced.

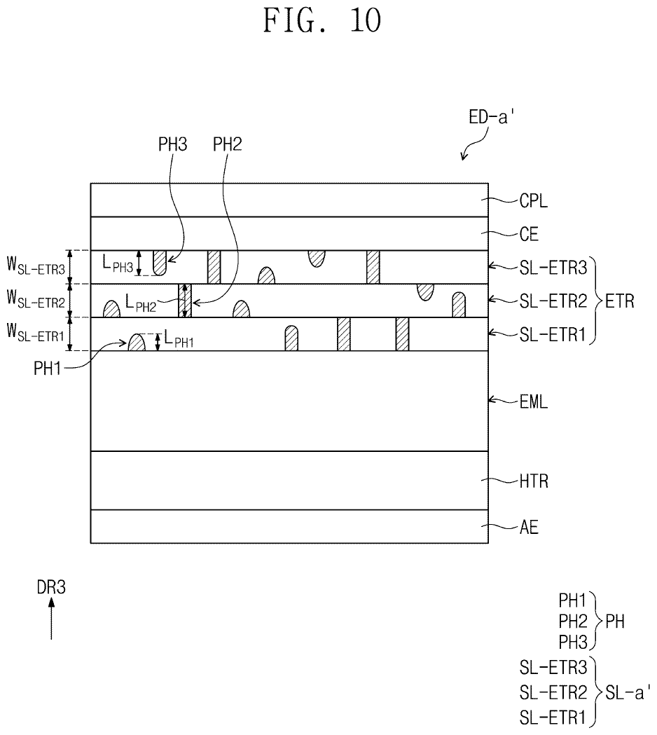

FIG. 10 is a cross-sectional view of an embodiment of a light-emitting element. FIG. 10 illustrates in detail the electron transport region ETR in FIG. 7.

Referring to FIG. 10, voids PH1, PH2 and PH3 are defined in a plurality of sub-layers SL-a′. A first sub-layer SL-ETR1 may include a first void PH1. A second void PH2 is defined in a second sub-layer SL-ETR2. A third void PH3 may be defined in a third sub-layer SL-ETR3. The voids PH1, PH2 and PH3 may have respective lengths L_{PH1}, L_{PH2} and L_{PH3} in a thickness direction of the plurality of sub-layers SL-a′.

In an embodiment, the lengths L_{PH1}, L_{PH2} and L_{PH3} of the voids PH1, PH2 and PH3 in the thickness direction of the plurality of sub-layers SL-a′ may be the same as or less than thicknesses W_{SL-ETR1}, W_{SL-ETR2} and W_{SL-ETR3} of the sub-layers SL-ETR1, SL-ETR2 and SL-ETR3, respectively. The length L_{PH1} of the first void PH1 in the thickness direction may be the same as or less than a first thickness W_{SL-ETR1} of the first sub-layer SL-ETR1. The length L_{PH2} of the second void PH2 in the thickness direction may be the same as or less than a second thickness W_{SL-ETR1} of the second sub-layer SL-ETR2. The length L_{PH3} of the third void PH3 in the thickness direction may be the same as or less than a third thickness W_{SL-ETR3} of the third sub-layer SL-ETR3. When the lengths L_{PH1}, L_{PH2} and L_{PH3} of the voids PH1, PH2 and PH3 in the thickness direction of the plurality of sub-layers SL-a′ are the same as or less than the thicknesses W_{SL-ETR1}, W_{SL-ETR2} and W_{SL-ETR3} of the sub-layers SL-ETR1, SL-ETR2 and SL-ETR3, respectively, diffusion of materials of layers directly disposed on the plurality of sub-layers SL-a′ may be suppressed, and thus a light-emitting element ED-a′ may exhibit relatively excellent luminescent properties. In an embodiment, as illustrated in FIG. 10, when the length Lpm of the first void PH1 in the thickness direction in the electron transport region ETR is the same as or less than the first thickness W_{SL-ETR1} of the first sub-layer SL-ETR1, a path along which a material of an emission layer EML is diffused into the electron transport region ETR may be suppressed, for example. In an embodiment, as illustrated in FIG. 10, when the length L_{PH3} of the third void PH3 in the thickness direction in the electron transport region ETR is the same as or less than the third thickness W_{SL-ETR3} of the third sub-layer SL-ETR3, a path along which a material of a second electrode CE is diffused into the electron transport region ETR may be suppressed, for example. The same principle may also apply to a case (FIG. 8) in which the emission layer EML includes the plurality of sub-layers and a case (FIG. 9) in which each of the emission layer EML and the electron transport region ETR includes the plurality of sub-layers.

In an embodiment, each of the voids PH1, PH2 and PH3 may not be connected to a void of a neighboring (adjacent) sub-layer among the sub-layers SL-ETR1, SL-ETR2 and SL-ETR3. The first void PH1 may not be connected to the second void PH2. The second void PH2 may not be connected to the third void PH3. When the voids are connected to each other in the emission layer EML and/or the electron transport region ETR, a material of a neighboring (adjacent) layer may be introduced through the connected voids. This may lead to a reduction in product quality of the light-emitting element. However, in the light-emitting element ED-a′ in an embodiment, the voids PH1, PH2 and PH3 may not be connected to each other but disconnected from each other, thereby blocking a path along which the material of the neighboring (adjacent) layer is diffused. Thus, the light-emitting element ED-a′ in an embodiment may have relatively excellent display quality and reliability.

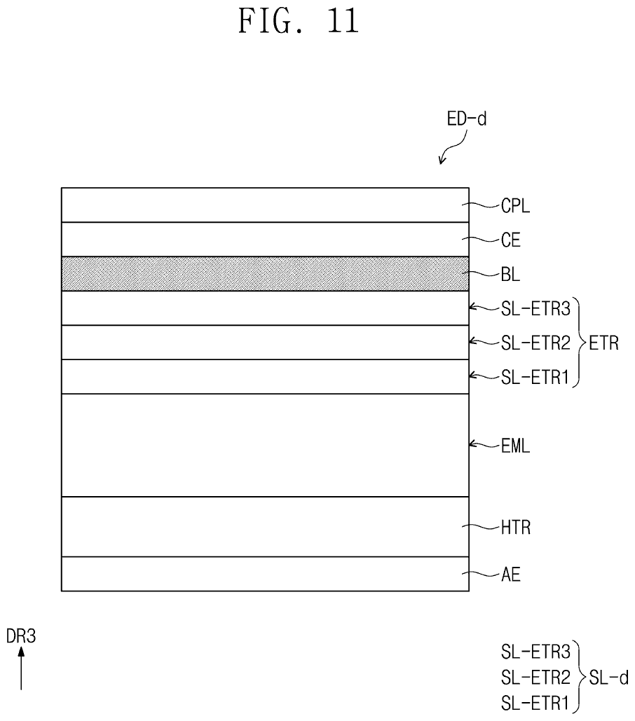

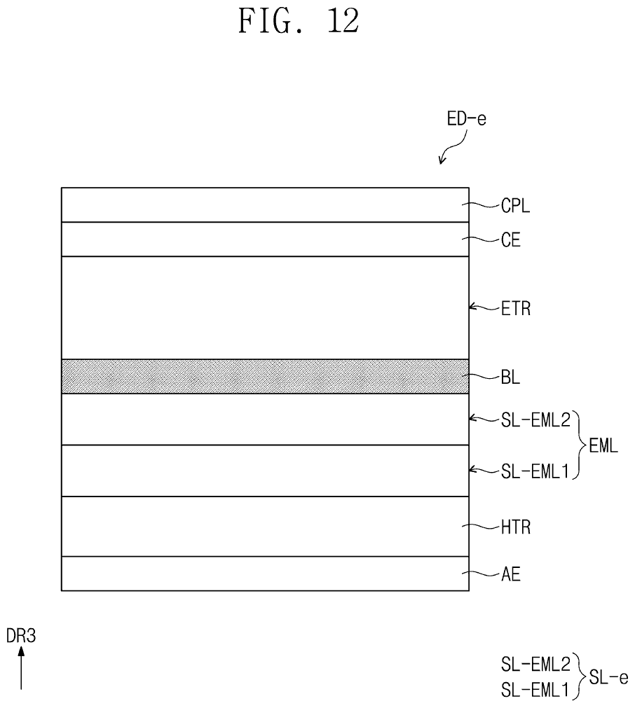

FIGS. 11 and 12 are each a cross-sectional view of an embodiment of a light-emitting element.

Each of light-emitting elements ED-d and ED-e in an embodiment may further include a block layer BL directly disposed on at least one of a top surface of an emission layer EML, a bottom surface of the emission layer EML, a top surface of an electron transport region ETR, or a bottom surface of the electron transport region ETR. FIG. 11 illustrates an embodiment of further including the block layer BL directly disposed on the top surface of the electron transport region ETR. FIG. 12 illustrates an embodiment of further including the block layer BL directly disposed on the top surface of the emission layer EML. However, the inventive concept is not limited thereto.

The block layer BL is a layer which prevents interlayer material diffusion in the light-emitting elements ED-d and ED-e. As the block layer BL prevents the interlayer material diffusion in the light-emitting elements ED-d and ED-e, the light-emitting elements ED-d and ED-e may exhibit relatively excellent element characteristics. The block layer BL may be an organic film, an inorganic film, or an organic/inorganic composite film. A material of the block layer BL may include Yb, Ag, Mg, or the like, but is not limited thereto.

Referring to FIG. 11, in the light-emitting element ED-d in an embodiment, the block layer BL may be disposed between the electron transport region ETR and a second electrode CE and prevent the interlayer material diffusion, e.g., suppressing diffusion of a metal material such as Ag of the second electrode CE into the electron transport region ETR. Referring to FIG. 12, in the light-emitting element ED-e in an embodiment, the block layer BL may be disposed between the emission layer EML and the electron transport region ETR and prevent the interlayer material diffusion, e.g., suppressing diffusion of a quantum dot component such as Se of the emission layer EML into the electron transport region ETR.

In the light-emitting element ED in an embodiment, a plurality of sub-layers SL may each independently further include at least one of Al₂O₃, TiO₂, SiO₂, BaSO₄, Ta₂O₅, PbCl₂, PbBr₂, PbI₂, ITO, Ag, ZnO, SnCl₂, SnBr₂, SnI₂, SnO, PVP, or PMMA. When the electron transport region ETR in the light-emitting element ED in an embodiment includes the plurality of sub-layers SL, in addition to an electron transport material, the sub-layers SL may each independently further include at least one of Al₂O₃, TiO₂, SiO₂, BaSO₄, Ta₂O₅, PbCl₂, PbBr₂, PbI₂, ITO, Ag, ZnO, SnCl₂, SnBr₂, SnI₂, SnO, PVP, or PMMA. When the emission layer EML in the light-emitting element ED in an embodiment includes the plurality of sub-layers SL, in addition to a light-emitting material, the sub-layers SL may each independently further include at least one of Al₂O₃, TiO₂, SiO₂, BaSO₄, Ta₂O₅, PbCl₂, PbBr₂, PbI₂, ITO, Ag, ZnO, SnCl₂, SnBr₂, SnI₂, SnO, PVP, or PMMA.

The foregoing materials such as Al₂O₃, which are included as additional material in the sub-layers, may function as additives for increasing density. The foregoing materials such as Al₂O₃, may increase physical density of the plurality of sub-layers SL to prevent a material of a neighboring (adjacent) layer from being introduced into the emission layer EML and/or the electron transport region ETR, thereby increasing material purity of each layer in the light-emitting element.

The light-emitting elements ED, ED-a, ED-b, ED-c, ED-a′, ED-d and ED-e in an embodiment, described with reference to FIGS. 6 to 12, may be included in an electronic device.

Referring to FIGS. 2 and 3, an electronic device EA in an embodiment may include a display device DD including a display module DM which displays an image, the display module DM may include a plurality of light-emitting elements, and the light-emitting elements may each include the characteristics of the light-emitting elements in an embodiment described above.

The electronic device in an embodiment may include the light-emitting elements in an embodiment described above, thereby exhibiting relatively excellent display quality and relatively excellent reliability characteristics.

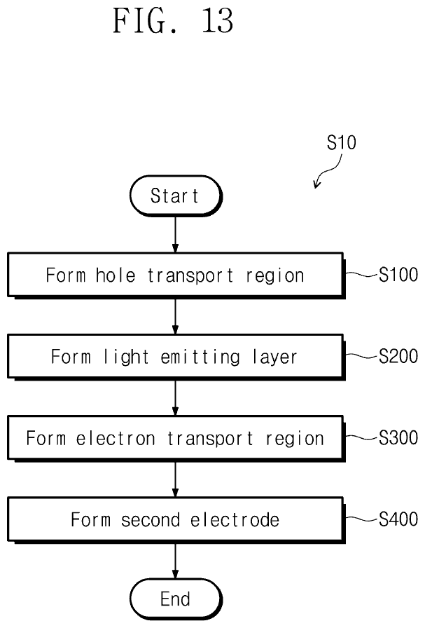

Hereinafter, a method for manufacturing a light-emitting element in an embodiment will be described with reference to FIGS. 13 to 15. The method for manufacturing the light-emitting element in an embodiment will be described by avoiding the contents in common with the contents about the light-emitting element in an embodiment described with reference to FIGS. 6 to 12, and mainly in terms of differences.

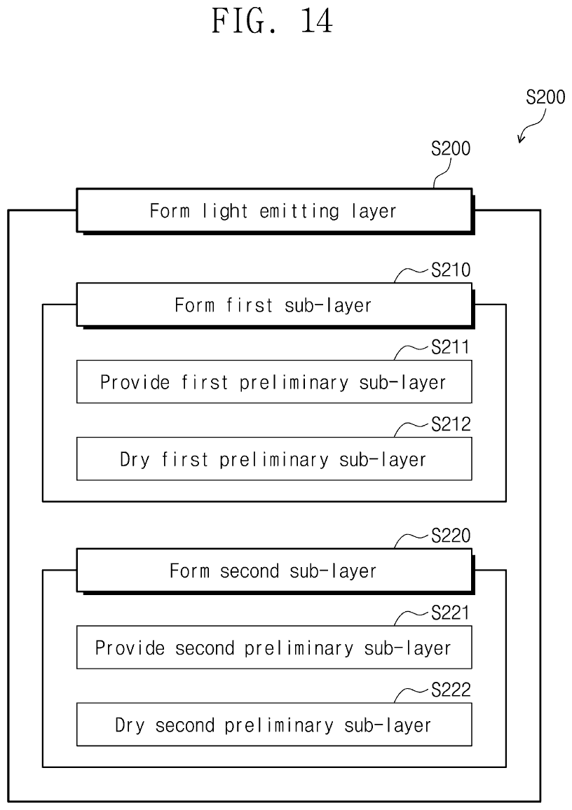

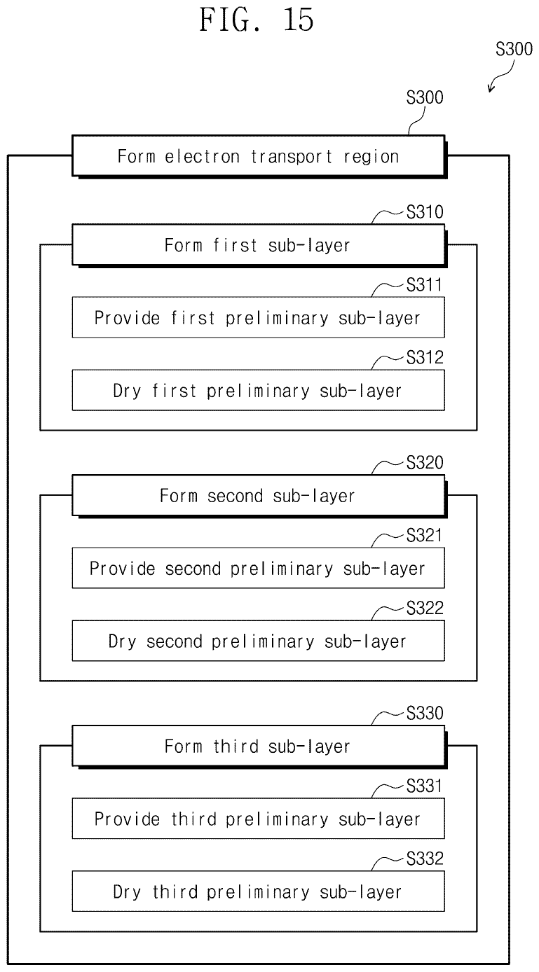

FIG. 13 is a flowchart illustrating an embodiment of a method for manufacturing a light-emitting element. FIGS. 14 and 15 are views illustrating embodiments of detailed operations of a method for manufacturing a light-emitting element.

Referring to FIGS. 13 to 15, a method for manufacturing a light-emitting element in an embodiment (S10) includes forming a hole transport region (S100), forming an emission layer (S200), forming an electron transport region (S300), and forming a second electrode (S400). Specifically, the method for manufacturing the light-emitting element in an embodiment (S10) includes the forming of the hole transport region on a first electrode (S100), the forming of the emission layer including a quantum dot on the hole transport region (S200), the forming of the electron transport region on the emission layer (S300), and the forming of the second electrode on the electron transport region (S400). At least one of the forming of the emission layer or the forming of the electron transport region includes performing formation of a sub-layer multiple times (S210, S220, S310, S320 and S330), and the performing of the formation of the sub-layer (S210, S220, S310, S320 and S330) includes providing a preliminary sub-layer (S211, S221, S311, S321 and S331) and drying the preliminary sub-layer (S212, S222, S312, S322 and S332).

FIG. 14 illustrates the forming of the emission layer (S200) in a method for manufacturing a light-emitting element in an embodiment in which an emission layer includes a plurality of sub-layers divided in the thickness direction. An example is illustrated of the method for manufacturing the light-emitting element in which the emission layer includes a first sub-layer and a second sub-layer, but the number of times of the formation of the sub-layer is not limited thereto. The formation of the first sub-layer (S210) includes providing a first preliminary sub-layer (S211) and drying the first preliminary sub-layer (S212). The formation of the second sub-layer (S220) includes providing a second preliminary sub-layer (S221) and drying the second preliminary sub-layer (S222).

FIG. 15 illustrates the forming of the electron transport region (S300) in a method for manufacturing a light-emitting element in an embodiment in which the electron transport region includes a plurality of sub-layers divided in the thickness direction. An example is illustrated of the method for manufacturing the light-emitting element in an embodiment in which the electron transport region includes a first sub-layer to a third sub-layer, but the number of times of the formation of the sub-layer is not limited thereto. The formation of the first sub-layer (S310) includes providing a first preliminary sub-layer (S311) and drying the first preliminary sub-layer (S312). The formation of the second sub-layer (S320) includes providing a second preliminary sub-layer (S321) and drying the second preliminary sub-layer (S322). The formation of the third sub-layer (S330) includes providing a third preliminary sub-layer (S331) and drying the third preliminary sub-layer (S332).

In the drying of the preliminary sub-layer (S212, S222, S312, S322 and S332), an H concentration of a top surface of the preliminary sub-layer may be decreased or increased by evaporation or contamination. Thus, in the light-emitting element manufactured by the method for manufacturing the light-emitting element in an embodiment, the H concentration measured along a thickness direction of the plurality of sub-layers may have a local minimum value or a local maximum value at an interface between the plurality of sub-layers. In the drying of the preliminary sub-layer (S212, S222, S312, S322 and S332), an F concentration of the top surface of the preliminary sub-layer may be decreased or increased by evaporation or contamination. Thus, in the light-emitting element manufactured by the method for manufacturing the light-emitting element in an embodiment, the F concentration measured along the thickness direction of the plurality of sub-layers may have a local minimum value or a local maximum value at the interface between the plurality of sub-layers.

In the drying of the preliminary sub-layer (S212, S222, S312, S322 and S332), a void may be generated in the sub-layers. Typically, when forming an emission layer and/or an electron transport region is performed once, a void having a long length in a thickness direction of the emission layer and/or the electron transport region is generated during drying of the emission layer and/or the electron transport region. Thus, a material of a neighboring (adjacent) layer is diffused in a stacking process, thereby leading to a reduction in display quality of a light-emitting element. When the forming of the emission layer and/or the electron transport region is performed multiple times, stacking and drying may be performed multiple times, which is effective in filling a void in a lower layer during stacking of an upper layer. Accordingly, a light-emitting element with voids reduced in number may be manufactured. Moreover, a position in which a void is generated may be different between the upper layer and the lower layer, thereby preventing a path along which a material of a neighboring (adjacent) layer is diffused. Therefore, the light-emitting element manufactured by the method for manufacturing the light-emitting element in an embodiment may exhibit the relatively excellent display quality and reliability.

In an embodiment, the preliminary sub-layer may be provided through inkjet printing. A void may be generated during the drying of the preliminary sub-layer provided through inkjet printing, and performing the formation of the sub-layer multiple times to provide the emission layer or the electron transport region may be effective in filling a void in a lower layer during stacking an upper layer, thereby minimizing the void generation.

In an embodiment, each of the plurality of sub-layers formed by repeating the formation of the sub-layer multiple times may be an organic/inorganic composite layer. The emission layer EML and/or the electron transport region ETR may be a layer including both an organic material and an inorganic material. In this case, the light-emitting element may exhibit relatively excellent optical properties.

In an embodiment, the formation of the sub-layer may be repeated two to five times. In a case in which the formation of the sub-layer is repeated six times or more, the sub-layers may each have an excessively relatively small thickness and be thus difficult to manufacture in a uniform thickness, and the display quality of the light-emitting element may be reduced.

In an embodiment, the preliminary sub-layers provided in the performing of the formation of the sub-layer multiple times may have the same material as each other. The sub-layers may be stacked in a multilayer structure without a change in material during the manufacture, thereby enabling rapid large-area fabrication of the light-emitting element.

In an embodiment, the plurality of sub-layers may have the same thickness. When the thicknesses of the plurality of sub-layers are the same, the display quality of the light-emitting element may be relatively excellent.

In an embodiment, forming a block layer may be further included before at least one of the forming of the emission layer (S200), the forming of the electron transport region (S300), or the forming of the second electrode (S400). Thus, the block layer may be directly disposed on at least one of a top surface of the emission layer, a bottom surface of the emission layer, a top surface of the electron transport region, or a bottom surface of the electron transport region, thereby preventing interlayer material diffusion in the light-emitting element. Thus, the light-emitting element in an embodiment may exhibit relatively excellent element characteristics.

In the method for manufacturing the light-emitting element in the embodiment, the at least one of the forming of the emission layer or the forming of the electron transport region may include the performing of the formation of the sub-layer multiple times, and each formation of the sub-layer may include the providing of the preliminary sub-layer and the drying of the preliminary sub-layer. Accordingly, the method may suppress the generation of the voids in the emission layer and/or the electron transport region and be used for the manufacture of the light-emitting element with the improved element characteristics.

In the light-emitting element in the embodiment, the at least one of the emission layer or the electron transport region may include the plurality of sub-layers divided in the thickness direction, and the H concentration measured along the thickness direction of the plurality of sub-layers may have the local minimum value or the local maximum value at the interface between the plurality of sub-layers. Accordingly, the generation of the voids in the emission layer and/or the electron transport region may be suppressed to suppress the diffusion of the material of the next (adjacent) layer, such as the second electrode, through the voids.

The electronic device in the embodiment may include the light-emitting elements, thereby exhibiting the improved display quality and reliability characteristics.

In the above, description has been made with reference to embodiments of the inventive concept, but those skilled or of ordinary skill in the art may understand that various modifications and changes may be made to the inventive concept insofar as such modifications and changes do not depart from the spirit and technical scope of the inventive concept set forth in the claims to be described later.

Therefore, the technical scope of the inventive concept is not to be limited to the contents stated in the detailed description of the specification, but should be determined by the claims.

What is claimed is:

1. A method for manufacturing a light-emitting element, the method comprising:
forming a hole transport region on a first electrode;
forming an emission layer comprising a quantum dot on the hole transport region;
forming an electron transport region on the emission layer; and
forming a second electrode on the electron transport region,
wherein at least one of the forming the emission layer or the forming the electron transport region comprises forming a sub-layer multiple times, and
wherein the forming the sub-layer comprises providing a preliminary sub-layer and drying the preliminary sub-layer.

2. The method of claim 1, wherein the preliminary sub-layer is provided through inkjet printing.

3. The method of claim 1, wherein each of a plurality of sub-layers formed by repeating the forming the sub-layer multiple times is an organic/inorganic composite layer.

4. The method of claim 1, wherein the forming the sub-layer is repeated two to five times.

5. The method of claim 1, wherein preliminary sub-layers provided in the performing the forming the sub-layer multiple times have same materials as each other.

6. The method of claim 1, wherein a plurality of sub-layers formed by repeating the forming the sub-layer multiple times have same thicknesses as each other.

7. The method of claim 1, further comprising forming a block layer before at least one of the forming the emission layer, the forming the electron transport region, or the forming the second electrode.

8. A light-emitting element comprising:
a first electrode;
a hole transport region disposed on the first electrode;
an emission layer disposed on the hole transport region and comprising a quantum dot;
an electron transport region disposed on the emission layer; and
a second electrode disposed on the electron transport region,
wherein at least one of the emission layer or the electron transport region comprises a plurality of sub-layers divided in a thickness direction,
wherein an H concentration measured along the thickness direction of the plurality of sub-layers has a local minimum value or a local maximum value at an interface between the plurality of sub-layers.

9. The light-emitting element of claim 8, wherein each of the plurality of sub-layers is an organic/inorganic composite layer.

10. The light-emitting element of claim 8, wherein the plurality of sub-layers have same thicknesses as each other.

11. The light-emitting element of claim 8, wherein the plurality of sub-layers are two to five in number.

12. The light-emitting element of claim 8, wherein a void is defined in each of the plurality of sub-layers,
wherein a length of the void in the thickness direction of the plurality of sub-layers is equal to or less than a thickness of each of the plurality of sub-layers.

13. The light-emitting element of claim 8, wherein a void is defined in each of the plurality of sub-layers,
wherein the void is not connected to a void of a neighboring sub-layer of the plurality of sub-layers.

14. The light-emitting element of claim 8, further comprising a block layer directly disposed on at least one of a top surface of the emission layer, a bottom surface of the emission layer, a top surface of the electron transport region, or a bottom surface of the electron transport region.

15. The light-emitting element of claim 8, wherein the plurality of sub-layers each independently further comprise at least one of Al₂O₃, TiO₂, SiO₂, BaSO₄, Ta₂O₅, PbCl₂, PbBr₂, PbI₂, indium tin oxide, Ag, ZnO, SnCl₂, SnBr₂, SnI₂, SnO, polyvinylpyrrolidone, or polymethyl methacrylate.

16. An electronic device comprising:
a display device comprising:
a display module configured to display an image, the display module comprising:
a plurality of light-emitting elements, each of the plurality of light-emitting elements comprising:
a first electrode;
a hole transport region disposed on the first electrode;
an emission layer disposed on the hole transport region and comprising a quantum dot;
an electron transport region disposed on the emission layer; and
a second electrode disposed on the electron transport region,
wherein at least one of the emission layer or the electron transport region comprises a plurality of sub-layers divided in a thickness direction, and
wherein an H concentration measured along the thickness direction of the plurality of sub-layers has a local minimum value or a local maximum value at an interface between the plurality of sub-layers.

17. The electronic device of claim 16, wherein each of the plurality of sub-layers is an organic/inorganic composite layer.

18. The electronic device of claim 16, wherein the plurality of sub-layers are two to five in number.

19. The electronic device of claim 16, further comprising at least one of a processor, a memory, or a power module.

20. The electronic device of claim 16, wherein the electronic device comprises the display module and is a television, a monitor, an outdoor billboard, a personal computer, a notebook computer, a personal digital assistant, a vehicle device, a game console, a smartphone, a tablet computer, a smartwatch, or a camera.
